(19) United States
(12) Patent Application Publication
(10) Pub. No.: US 2012/0200443 A1
(43) Pub. Date: Aug. 9, 2012

(54) SIGNAL PROCESSING CIRCUIT

(75) Inventor: Yuichiro MORI, Aichi (JP)

(73) Assignee: KABUSHIKI KAISHA TOKAI RIKA DENKI SEISAKUSHO, Aichi (JP)

(21) Appl. No.: 13/362,066

(22) Filed: Jan. 31, 2012

(30) Foreign Application Priority Data
Feb. 9, 2011 (JP) 2011-025666

(51) Int. Cl. H03M 1/12

(52) U.S. Cl. 341/155

(57) ABSTRACT

A signal processing circuit includes an encoder configured to encode a digital signal inputted thereto and output an encode signal, and a memory electrically connected to a first input terminal and the encoder. The memory is configured to store information based on the encode signal outputted from the encoder therein, based on a first write signal inputted via the first input terminal.

The present application is based on Japanese patent application No. 2011-025666 filed on Feb. 9, 2011, the entire contents of which are incorporated herein by reference.

### BACKGROUND OF THE INVENTION

1. Field of the Invention

This invention relates to a signal processing circuit.

2. Description of the Related Art

As a conventional technique, a system is known that includes a serial EEPROM (Electrically Erasable and Programmable Read Only Memory) configured to store data therein, and a serial EEPROM interface configured to execute data transfer to and from the serial EEPROM (for example, refer to JP-A-2004-110407).

In addition, the serial EEPROM interface includes a status store register configured to be able to be accessed from a host CPU, a command publication interval setting register configured to be able to be accessed from the host CPU, a timer configured to count an arbitrary clock, a status read command automatic publication means configured to automatically publish a status read command when a timer value of the timer and a value of the command publication interval setting register are equalized, and a timer stop means configured to start the count of the timer when the serial EEPROM starts to access, and to stop the count of the timer when a busy bit of the status store register is negated.

According to the system, the system load can be reduced without requiring a complicated control.

However, the conventional system carries out a serial communication of SPI (Serial Peripheral Interface), thus the system has a problem that the above-mentioned configuration is needed in the serial EEPROM interface so that the circuit area becomes large.

### SUMMARY OF THE INVENTION

Accordingly, it is an object of the invention to provide a signal processing circuit with a downsized footprint.

(1) According to one embodiment of the invention, a signal processing circuit comprises:

an encoder configured to encode a digital signal inputted thereto and output an encode signal; and

a memory electrically connected to a first input terminal and the encoder, wherein the memory is configured to store information based on the encode signal outputted from the encoder therein, based on a first write signal inputted via the first input terminal.

In the above embodiment (1) of the invention, the following modifications and changes can be made.

(i) The signal processing circuit further comprises:

an A/D conversion part electrically connected to a second input terminal and the encoder, wherein the A/D conversion part is configured to convert an analog signal inputted thereto via the second input terminal into a digital signal and output the digital signal to the encoder.

(ii) The signal processing circuit further comprises:

a switch provided between the A/D conversion part and the encoder; and

a switch control part electrically connected to a third input terminal,

wherein the switch control part is configured to control the switch according to a control signal inputted thereto via the third input terminal to provide an electrical connection between the A/D conversion part and the encoder.

(iii) The switch control part is electrically connected to the memory, and configured to output a second write signal to the memory based on the control signal inputted thereto via the third input terminal, and the memory is configured to store the information therein based on the second write signal.

(2) According to another embodiment of the invention, a signal processing circuit comprises:

an encoder configured to encode a digital signal inputted thereto and output an encode signal;

a memory electrically connected to the encoder; and

a switch control part electrically connected to the memory and a third input terminal,

wherein the memory is configured to store information based on the encode signal outputted from the encoder therein, based on a second write signal inputted via the third input terminal.

In the above embodiment (2) of the invention, the following modifications and changes can be made.

(iv) The signal processing circuit further comprises:

an A/D conversion part electrically connected to a second input terminal and the encoder, wherein the A/D conversion part is configured to convert an analog signal inputted thereto via the second input terminal into a digital signal and output the digital signal to the encoder.

(v) The signal processing circuit further comprises:

a switch provided between the A/D conversion part and the encoder, wherein the switch control part is configured to control the switch according to a control signal inputted thereto via the third input terminal to provide an electrical connection between the A/D conversion part and the encoder.

(vi) The third input terminal comprises a power supply (Vcc) terminal.

### Effects of the Invention

According to one embodiment of the invention, a signal processing circuit with a downsized footprint can be provided.

### BRIEF DESCRIPTION OF THE DRAWINGS

The preferred embodiments according to the invention will be explained below referring to the drawings, wherein:

FIG. 1 is a block diagram showing a signal processing circuit according to a first embodiment of the invention;

FIG. 2A is a graph showing a relationship between an input signal input into the signal processing circuit and an output signal output from the signal processing circuit according to the first embodiment;

FIG. 2B is a correspondence table between a voltage and a digital value;

FIG. 3 is a block diagram showing a signal processing circuit according to a second embodiment of the invention; and

FIG. 4 is a block diagram showing a signal processing circuit according to a third embodiment of the invention.

### DETAILED DESCRIPTION OF THE PREFERRED EMBODIMENTS

### Summary of Embodiments

A signal processing circuit according to the embodiments includes an encoder configured to encode a digital signal input so as to produce an encode signal and a memory electrically connected to a first input terminal and the encoder, and configured to store information therein based on the encode signal output from the encoder based on a first write signal input via the first input terminal.

### First Embodiment

Configuration of Signal Processing Circuit 1

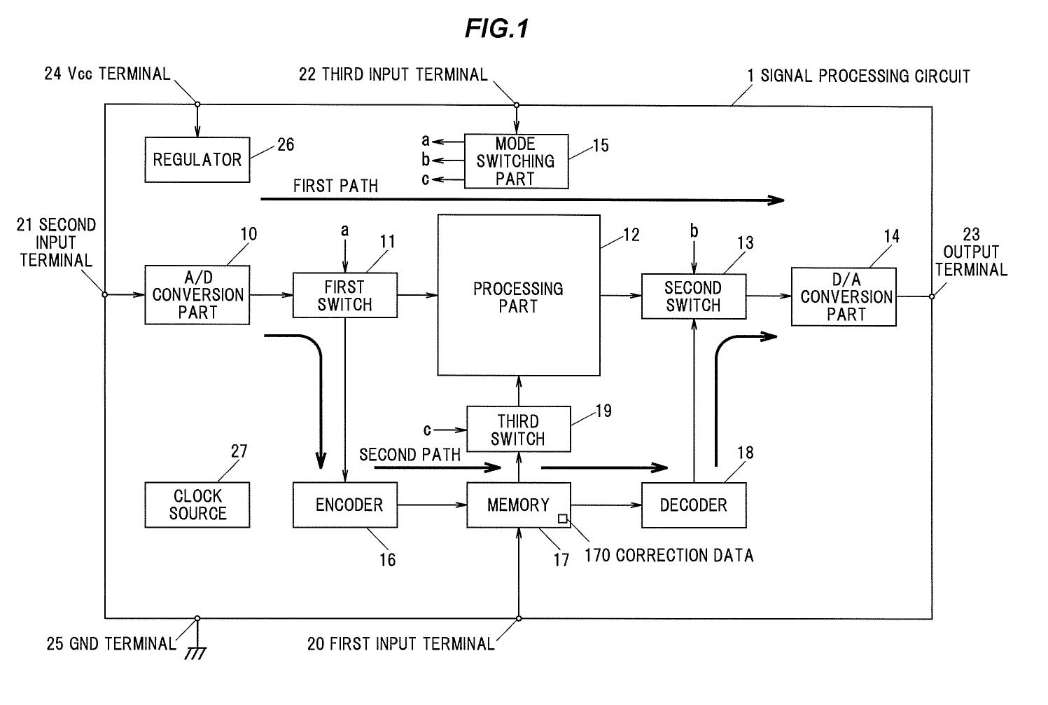

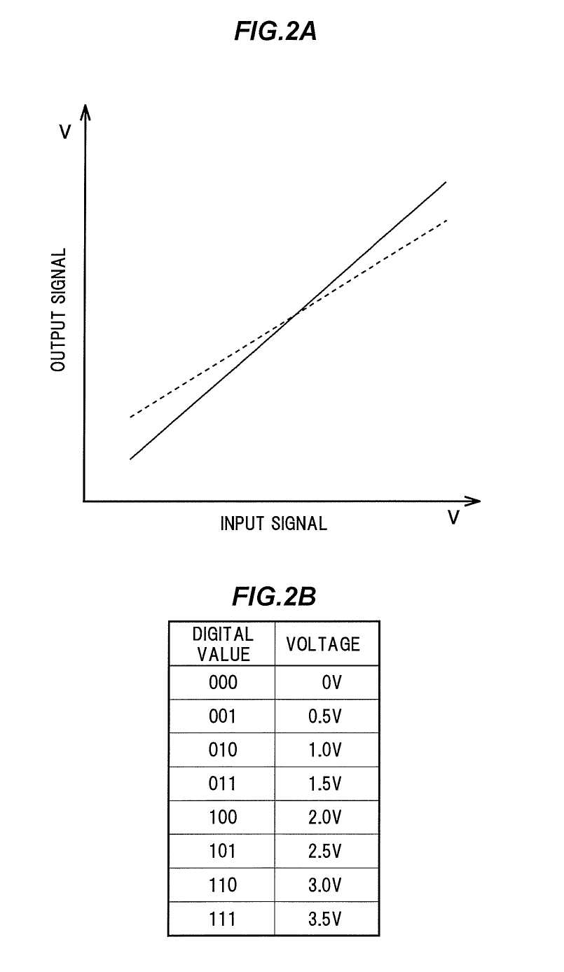

FIG. 1 is a block diagram showing a signal processing circuit according to a first embodiment of the invention. FIG. 2A is a graph showing a relationship between an input signal input into the signal processing circuit and an output signal output from the signal processing circuit according to the first embodiment, and FIG. 2B is a correspondence table between a voltage and a digital value. In FIG. 1, arrowed lines (a), (b) and (c) connected to a mode switching part 15 show that the mode switching part 15 is electrically connected to a first switch 11, a second switch 13 and a third switch 19 respectively. In FIG. 2A, the horizontal axis shows an input signal (a voltage V) and the vertical axis shows an output signal (a voltage V). In addition, in FIG. 2A, the continuous line shows a relationship between an input and an output after correction, and the broken line shows a relationship between the input and the output before correction.

The signal processing circuit 1 is roughly configured to execute a write processing of information in a memory 17 without using an advanced communication protocol needed for the serial communication. Hereinafter, a particular configuration of the signal processing circuit 1 will be explained.

As shown in FIG. 1, the signal processing circuit 1 is roughly configured to mainly include an A/D conversion part 10 electrically connected to a second input terminal 21 and configured to convert an analog signal input into the second input terminal 21 to a digital signal, a processing part 12 configured to execute a processing to the digital signal converted by the A/D conversion part 10, a D/A conversion part 14 electrically connected to an output terminal 23 and configured to convert the digital signal processed by the processing part 12 to an analog signal so as to output the analog signal from the output terminal 23, a first switch 11 installed between the A/D conversion part 10 and the processing part 12, and a second switch 13 installed between the processing part 12 and the D/A conversion part 14, a mode switching part 15 electrically connected to a third input terminal 22 and configured to control the first switch 11, the second switch 12 and the third switch 19 based on a control signal input into the third input terminal 22, a memory 17 configured to store a correction data 170 therein, and the third switch 19 installed between the processing part 12 and the memory 17 and electrically connected to the mode switching part 15.

In addition, as shown in FIG. 1, the signal processing circuit 1 is roughly configured to further include an encoder 16 of which one end is electrically connected to the first switch 11 and another end is electrically connected to the memory 17 and configured to encode a digital signal input from the A/D conversion part 10 via the first switch 11 so as to produce an encode signal, and a decoder 18 of which one end is electrically connected to the second switch 13 and another end is electrically connected to the memory 17 and configured to decode the correction data 170 output from the memory 17 so as to produce a decode signal.

In addition, as shown in FIG. 1, the signal processing circuit 1 further includes a regulator 26 electrically connected to a Vcc terminal 24, a clock source 27, and a GND terminal 25 connected to GND (earth ground).

The A/D conversion part 10 is configured to, for example, convert an input analog signal to a digital signal in synchronization with a supplied clock signal described below. In particular, for example, when an analog signal having a voltage of 3V is input, as shown in FIG. 2B, the A/D conversion part 10 converts the analog signal to a digital signal of “1 1 0”. With regard to the relationship between the voltage and the digital value according to the embodiment, as one example, as shown in a correspondence table of FIG. 2B, the voltage of 0V corresponds to the digital value of “000”, 0.5V corresponds to “0 0 1”, 1.0V corresponds to “0 1 0”, 1.5V corresponds to “0 1 1”, 2.0V corresponds to “1 0 0”, 2.5V corresponds to “1 0 1”, 3.0V corresponds to “1 1 0”, 3.5V corresponds to “1 1 1” respectively.

The first switch 11 is configured to connect the processing part 12 or the encoder 16 to the A/D conversion part 10 by the control of the mode switching part 15.

The processing part 12 according to the embodiment is configured to, for example, execute a correction processing of correcting a digital signal output from the A/D conversion part 10. In particular, the processing part 12 is configured to, for example, correct the digital signal of “1 1 0” output from the A/D conversion part 10 to the digital signal of “1 1 1” based on the correction data 170 stored in the memory 17. The correction processing includes, for example, an offset processing and a gain processing based on the correction data 170.

The offset processing is, for example, a processing of increasing or decreasing the voltage before conversion of the digital signal input into the processing part 12 by a predetermined amount of voltage from the voltage. The offset processing according to the embodiment executes, as one example, a correction such that when the digital signal input is converted to an analog signal, a voltage of 0.5V is increased from the voltage before the conversion. The offset processing is, for example, a processing of correcting the variation of center value of the input signal input into the signal processing circuit 1 so as to produce an output signal.

The gain processing is, for example, a processing of increasing or decreasing the voltage before conversion of the digital signal input into the processing part 12 by a predetermined constant times of the voltage. The gain processing according to the embodiment executes, as one example, a correction such that when the digital signal input is converted to an analog signal, the voltage before the conversion becomes a voltage of one time of the voltage. The gain processing is, for example, a processing of correcting the variation of amplification magnification of the input signal input into the signal processing circuit 1 so as to produce an output signal. The above-mentioned gain processing and offset processing are continuously executed, and the digital signal produced by the gain processing and the offset processing is output from the processing part 12.

The second switch 13 is configured to connect the processing part 12 or the decoder 18 to the D/A conversion part 14 by the control of the mode switching part 15.

The D/A conversion part 14 is configured to, for example, convert a digital signal input to an analog signal in synchronization with a supplied clock signal. In particular, for example, when a digital signal of “1 1 1” is output from the processing part 12, as shown in the correspondence table of FIG. 2B, the D/A conversion part 14 converts the digital signal to an analog signal having a voltage of 3.5V.

The mode switching part 15 is configured to, for example, output a switch control signal that controls the first switch 11, the second switch 13, and the third switch 19. The mode switching part 15 is configured to output an analog signal input into the second input terminal 21 from the output terminal 23 as an analog signal passed through a first path and a second path based on the control signal input.

As shown in FIG. 1, the first path is a path of passing through the second input terminal 21, the A/D conversion part 10, the first switch 11, the processing part 12, the second switch 13, the D/A conversion part 14 and the output terminal 23. Consequently, the first path is a path of applying a processing predetermined in the signal processing circuit 1 to an analog signal input so as to output the analog signal.

In addition, as shown in FIG. 1, the second path is a path of passing through the second input terminal 21, the A/D conversion part 10, the first switch 11, the encoder 16, the memory 17, the decoder 18, the second switch 13, the D/A conversion part 14 and the output terminal 23. Consequently, the second path is a path of storing the correction data 170 in the memory 17, the correction data 170 being based on the analog signal input.

The encoder 16 is configured to, for example, convert the digital signal converted by the A/D conversion part 10 to an encode signal having a format that can be stored in the memory 17 in synchronization with a supplied clock signal.

The memory 17 is configured to, for example, store the above-mentioned correction data 170 therein. The memory 17 is configured to become “hi” when a voltage of not less than a predetermined threshold value (for example, 20 to 30V) is applied via the first input terminal 20, and become “low” when a voltage of less than a predetermined threshold value is applied via the first input terminal 20. The memory 17 is configured to execute the write processing when it is “hi”.

The decoder 18 is configured to, for example, decode the correction data 170 obtained from the memory 17 in synchronization with a supplied clock signal.

The third switch 19 is configured to electrically connect the memory 17 to the processing part 12 by control of the mode switching part 15.

In the second path, the D/A conversion part 14 is configured to convert the signal decoded by the decoder 18 to an analog signal so as to output the analog signal via the output terminal 23.

The regulator 26 is configured to, for example, supply a voltage (for example, 5V) that is necessary for the signal processing circuit 1 to operate by using a voltage Vcc (for example, 24V) applied via the Vcc terminal 24.

The clock source 27 is configured to, for example, supply a clock signal that is necessary for the signal processing circuit 1 to operate.

Hereinafter, an operation of the signal processing circuit 1 according to the embodiment will be explained. First, an operation in the first path will be explained.

Operation of the First Embodiment

With Regard to First Path

When a control signal that designates the first path is input via the third input terminal 22, the mode switching part 15 of the signal processing circuit 1 outputs a switch control signal that controls the first switch 11, the second switch 13 and the third switch 19 based on the control signal. By the above-mentioned control, the processing part 12 is electrically connected to the A/D conversion part 10, the D/A conversion part 14 and the memory 17.

Then, the A/D conversion part 10 converts an analog signal input via the second input terminal 21 to a digital signal.

Then, the processing part 12 retrieves the correction data 170 from the memory 17 via the third switch 19 so as to execute a correction processing of the digital signal input via the first switch 11 based on the correction data 170.

Then, the D/A conversion part 14 converts the digital signal input via the second switch 13, to which the correction processing is executed, to an analog signal so as to output via the output terminal 23.

By the correction processing, for example, a straight line shown by a broken line in FIG. 2A is corrected to a straight line shown by a continuous line in FIG. 2A so that a desired relationship between input and output can be obtained.

With Regard to Second Path

When a control signal that designates the second path is input via the third input terminal 22, the mode switching part 15 of the signal processing circuit 1 outputs a switch control signal that controls the first switch 11, the second switch 13 and the third switch 19 based on the second control signal. By the above-mentioned control, the encoder 16 is electrically connected to the A/D conversion part 10 and the memory 17, and the decoder 18 is electrically connected to the D/A conversion part 14 and the memory 17. In addition, the memory 17 is released from the connection with the processing part 12.

Then, the A/D conversion part 10 converts an analog signal input via the second input terminal 21, that becomes a correction data, to a digital signal.

Then, the encoder 16 encodes the digital signal input via the first switch 11 so as to produce an encode signal.

Then, in order to write the correction data 170, a voltage of not less than the threshold value is applied to the memory 17 via the first input terminal 20, and the memory 17 stores the correction data 170 therein based on the encode signal, and simultaneously outputs the stored correction data 170 to the decoder 18.

Then, the decoder 18 decodes the correction data 170 output from the memory 17 so as to produce a decode signal.

Then, the D/A conversion part 14 converts the decode signal input via the second switch 13 to an analog signal so as to output from the output terminal 23. Subsequently, a control part (not shown) connected to the signal processing circuit 1 checks the correction data 170 stored in the memory 17 based on the analog signal output.

With Regard to Third Path

Further, in the above, the first path and second path have been explained, but the signal processing circuit 1 can further include a third path configured to output the input signal without any change. In this case, the mode switching part 15 is configured to, for example, be further electrically connected to the processing part 12 so as to output a control signal instructing that the input signal is to be output without executing a correction processing thereto, to the processing part 12.

Namely, when a control signal that designates the third path is input via the third input terminal 22, the mode switching part 15 of the signal processing circuit 1 outputs a switch control signal that controls the first switch 11 and the second switch 13 based on the control signal. By the above-mentioned control, the processing part 12 is electrically connected to the A/D conversion part 10 and the D/A conversion part 14.

Then, the A/D conversion part 10 converts the analog signal input via the second input terminal 21 to a digital signal.

Then, the processing part 12 outputs the digital signal input via the first switch 11 without executing the correction processing based on the control signal input from the mode switching part 15.

Then, the D/A conversion part 14 converts the digital signal input via the second switch 13 to an analog signal so as to output the analog signal via the output terminal 23.

By the third path, the signal input into the signal processing circuit 1 can be checked.

Advantages of the First Embodiment

In accordance with the signal processing circuit 1 according to the first embodiment, the circuit scale is downsized in comparison with a case that the write processing is executed in the memory by using a serial communication of which circuit scale becomes larger than the encoder and decoder, thus the footprint on a chip can be downsized.

In addition, in accordance with the signal processing circuit 1 according to the first embodiment, the write processing can be executed without carrying out a serial communication with the memory, so that the processing time in the signal processing circuit 1 can be reduced in comparison with a case that the write processing is executed by using the serial communication.

### Second Embodiment

The second embodiment is different from the first embodiment in that a single switch control part executes the selection of the path and the instructions of write processing to the memory. Further, hereinafter, to the same elements in configures and functions as those of the first embodiment, the same references as used in the first embodiment will be used, and detail explanation will be omitted. Hereinafter, in particular, the voltage detection part 28 that is an element different from that of the first embodiment will be explained.

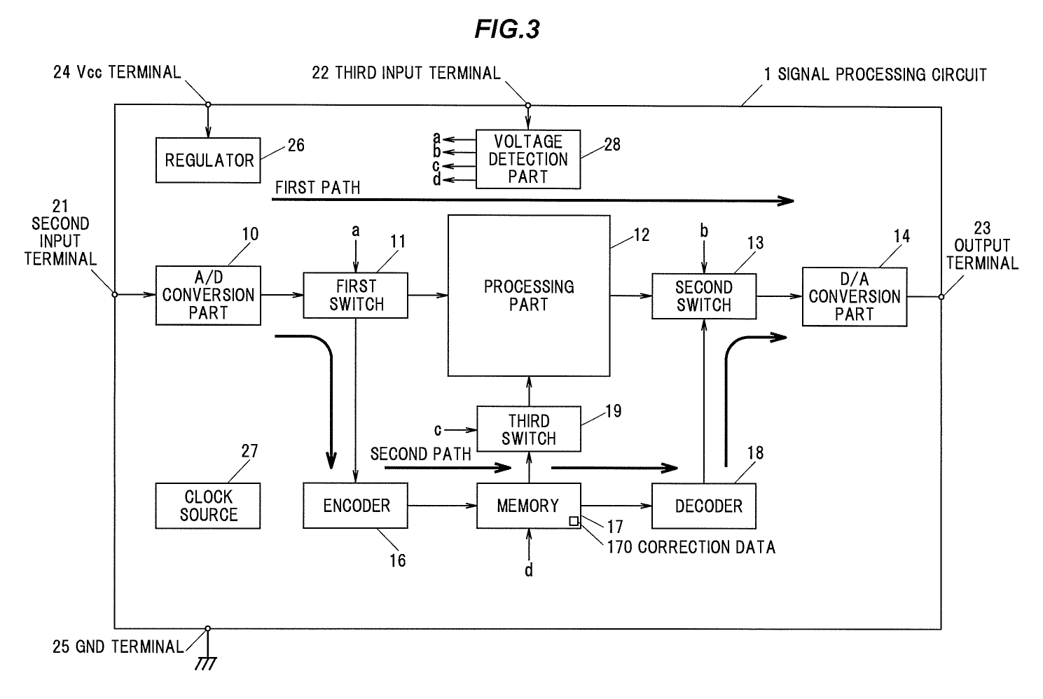

FIG. 3 is a block diagram showing a signal processing circuit according to the second embodiment of the invention. In FIG. 3, arrowed lines (a), (b), (c) and (d) connected to the voltage detection part 28 show that the voltage detection part 28 is electrically connected to the first switch 11, the second switch 13, the third switch 19 and the memory 17 respectively.

As shown in FIG. 3, the signal processing circuit 1 according to the embodiment includes the voltage detection part 28 as a switch control part.

The voltage detection part 28 is configured to be electrically connected to the third input terminal 22, the first switch 11, the second switch 13, the third switch 19 and the memory 17.

Further, the first switch 11 is configured to, for example, be electrically connected to the encoder 16 by that the switch control signal output from the voltage detection part 28 is input into the first switch 11. In addition, the second switch 13 is configured to, for example, be electrically connected to the decoder 18 by that the switch control signal output from the voltage detection part 28 is input into the second switch 13. Furthermore, the third switch 19 is configured to, for example, be released from the electrical connection with the processing part 12 by that the switch control signal output from the voltage detection part 28 is input into the third switch 19. Namely, the signal processing circuit 1 according to the embodiment is configured such that when the switch control signal is not output from the voltage detection part 28, the first path is formed, and when the switch control signal is output from the voltage detection part 28, the second path is formed.

The voltage detection part 28 is configured to output the switch control signal depending on the voltage of the control signal input. The voltage detection part 28 is configured to, for example, output the switch control signal when the control signal of not less than the threshold value is input into the voltage detection part 28.

Further, the memory 17 is configured to execute the write processing of storing the correction data 170 therein by using the switch control signal output from the voltage detection part 28 as the write signal.

Operation of the Second Embodiment

With Regard to First Path

When a control signal that designates the first path is input via the third input terminal 22, the voltage detection part 28 of the signal processing circuit 1 outputs a switch control signal that controls the first switch 11, the second switch 13 and the third switch 19 based on the control signal. By the above-mentioned control, the processing part 12 is electrically connected to the A/D conversion part 10, the D/A conversion part 14 and the memory 17.

Then, the A/D conversion part 10 converts an analog signal input via the second input terminal 21 to a digital signal.

Then, the processing part 12 retrieves the correction data 170 from the memory 17 via the third switch 19 so as to execute a correction processing of the digital signal input via the first switch 11 based on the correction data 170.

Then, the D/A conversion part 14 converts the digital signal input via the second switch 13, to which the correction processing is executed, to an analog signal so as to output via the output terminal 23.

By the correction processing, for example, a straight line shown by a broken line in FIG. 2A is corrected to a straight line shown by a continuous line in FIG. 2A so that a desired relationship between input and output can be obtained.

With Regard to Second Path

When a control signal that designates the second path is input via the third input terminal 22, the voltage detection part 28 of the signal processing circuit 1 outputs a switch control signal that controls the first switch 11, the second switch 13 and the third switch 19 based on the second control signal. By the above-mentioned control, the encoder 16 is electrically connected to the A/D conversion part 10 and the memory 17, and the decoder 18 is electrically connected to the D/A conversion part 14 and the memory 17. In addition, the memory 17 is released from the connection with the processing part 12.

Then, the A/D conversion part 10 converts an analog signal input via the second input terminal 21, that becomes a correction data, to a digital signal.

Then, the encoder 16 encodes the digital signal input via the first switch 11 so as to produce an encode signal.

Then, in order to write the correction data 170, a voltage of not less than the threshold value is applied to the memory 17 via the voltage detection part 28, and the memory 17 stores the correction data 170 therein based on the encode signal, and simultaneously outputs the stored correction data 170 to the decoder 18.

Then, the decoder 18 decodes the correction data 170 output from the memory 17 so as to produce a decode signal.

Then, the D/A conversion part 14 converts the decode signal input via the second switch 13 to an analog signal so as to output from the output terminal 23. Subsequently, a control part (not shown) connected to the signal processing circuit 1 checks the correction data 170 stored in the memory 17 based on the analog signal output.

With Regard to Third Path

Further, in the above, the first path and second path have been explained, but the signal processing circuit 1 can further include a third path configured to output the input signal without any change. In this case, the voltage detection part 28 is configured to, for example, be further electrically connected to the processing part 12 so as to output a control signal instructing that the input signal is to be output without executing a correction processing thereto, to the processing part 12.

Namely, when a control signal that designates the third path is input via the third input terminal 22, the voltage detection part 28 of the signal processing circuit 1 outputs a switch control signal that controls the first switch 11 and the second switch 13 based on the control signal. By the above-mentioned control, the processing part 12 is electrically connected to the A/D conversion part 10 and the D/A conversion part 14.

Then, the A/D conversion part 10 converts the analog signal input via the second input terminal 21 to a digital signal.

Then, the processing part 12 outputs the digital signal input via the first switch 11 without executing the correction processing based on the control signal input from the voltage detection part 28.

Then, the D/A conversion part 14 converts the digital signal input via the second switch 13 to an analog signal so as to output the analog signal via the output terminal 23.

By the third path, the signal input into the signal processing circuit 1 can be checked.

Advantages of the Second Embodiment

In accordance with the signal processing circuit 1 according to the embodiment, the number of terminal thereof is less than that of the signal processing circuit according to the first embodiment by one terminal, thus the footprint can be further downsized.

### Third Embodiment

The third embodiment is different from each of the above-mentioned embodiments in that the third input terminal 22 is not needed.

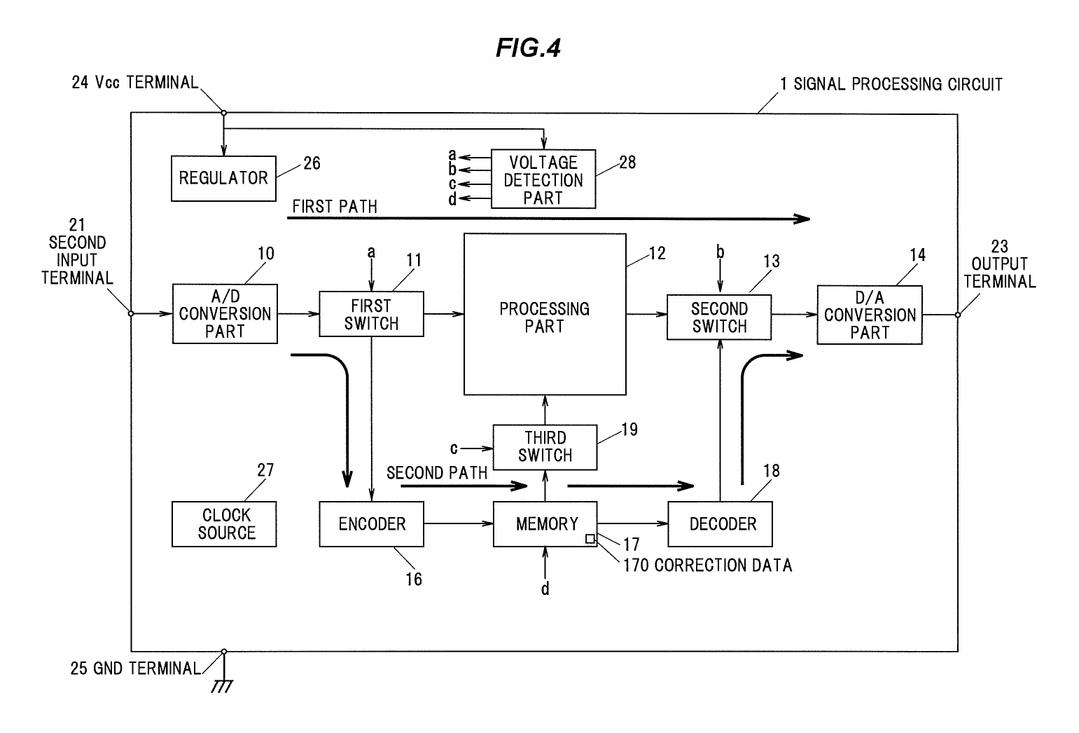

FIG. 4 is a block diagram showing a signal processing circuit according to the third embodiment of the invention.

The signal processing circuit 1 according to the embodiment is configured such that a voltage input from the Vcc terminal 24 is supplied to the regulator 26 and the voltage detection part 28.

The regulator 26 is configured to, for example, supply a voltage that is necessary for the signal processing circuit 1 to operate by using a voltage Vcc applied via the Vcc terminal 24 similarly to each of the embodiments.

The voltage detection part 28 is configured to, for example, output the switch control signal depending on the voltage Vcc applied via the Vcc terminal 24.

Operation of the Third Embodiment

With Regard to First Path

When a control signal that designates the first path is input via the Vcc terminal 24, the voltage detection part 28 of the signal processing circuit 1 outputs a switch control signal that controls the first switch 11, the second switch 13 and the third switch 19 based on the control signal. By the above-mentioned control, the processing part 12 is electrically connected to the A/D conversion part 10, the D/A conversion part 14 and the memory 17. The following operation is similar to that of the second embodiment.

With Regard to Second Path

When a control signal that designates the second path is input via the Vcc terminal 24, the voltage detection part 28 of the signal processing circuit 1 outputs a switch control signal that controls the first switch 11, the second switch 13 and the third switch 19 based on the second control signal. By the above-mentioned control, the encoder 16 is electrically connected to the A/D conversion part 10 and the memory 17, and the decoder 18 is electrically connected to the D/A conversion part 14 and the memory 17. In addition, the memory 17 is released from the connection with the processing part 12. The following operation is similar to that of the second embodiment.

With Regard to Third Path

Further, in the above, the first path and second path have been explained, but the signal processing circuit 1 can further include a third path configured to output the input signal without any change. In this case, the voltage detection part 28 is configured to, for example, be further electrically connected to the processing part 12 so as to output a control signal instructing that the input signal is to be output without executing a correction processing thereto, to the processing part 12.

Namely, when a control signal that designates the third path is input via the Vcc terminal 24, the voltage detection part 28 of the signal processing circuit 1 outputs a switch control signal that controls the first switch 11 and the second switch 13 based on the control signal. By the above-mentioned control, the processing part 12 is electrically connected to the A/D conversion part 10 and the D/A conversion part 14. The following operation is similar to that of the second embodiment.

Advantages of the Third Embodiment

In accordance with the signal processing circuit 1 according to the embodiment, the number of terminal thereof is less than that of the signal processing circuit according to each of the above-mentioned embodiments, thus the footprint can be further downsized.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A signal processing circuit, comprising:
an encoder configured to encode a digital signal inputted thereto and output an encode signal; and
a memory electrically connected to a first input terminal and the encoder,
wherein the memory is configured to store information based on the encode signal outputted from the encoder therein, based on a first write signal inputted via the first input terminal.

2. The signal processing circuit according to claim 1, further comprising an A/D conversion part electrically connected to a second input terminal and the encoder,
wherein the A/D conversion part is configured to convert an analog signal inputted thereto via the second input terminal into a digital signal and output the digital signal to the encoder.

3. The signal processing circuit according to claim 2, further comprising:
a switch provided between the A/D conversion part and the encoder; and
a switch control part electrically connected to a third input terminal,
wherein the switch control part is configured to control the switch according to a control signal inputted thereto via the third input terminal to provide an electrical connection between the A/D conversion part and the encoder.

4. The signal processing circuit according to claim 3, wherein the switch control part is electrically connected to the memory, and configured to output a second write signal to the memory based on the control signal inputted thereto via the third input terminal, and
wherein the memory is configured to store the information therein based on the second write signal.

5. A signal processing circuit, comprising:
an encoder configured to encode a digital signal inputted thereto and output an encode signal;
a memory electrically connected to the encoder; and
a switch control part electrically connected to the memory and a third input terminal,
wherein the memory is configured to store information based on the encode signal outputted from the encoder therein, based on a second write signal inputted via the third input terminal.

6. The signal processing circuit according to claim 5, further comprising an A/D conversion part electrically connected to a second input terminal and the encoder,
wherein the A/D conversion part is configured to convert an analog signal inputted thereto via the second input terminal into a digital signal and output the digital signal to the encoder.

7. The signal processing circuit according to claim 6, further comprising a switch provided between the A/D conversion part and the encoder,
wherein the switch control part is configured to control the switch according to a control signal inputted thereto via the third input terminal to provide an electrical connection between the A/D conversion part and the encoder.

8. The signal processing circuit according to claim 5, wherein the third input terminal comprises a power supply terminal.
